(19) United States
(12) Patent Application Publication
(10) Pub. No.: US 2005/0029541 A1
(43) Pub. Date: Feb. 10, 2005

(54) Charge controlled avalanche photodiode and method of making the same

(76) Inventor: Cheng C. Ko, Ann Arbor, MI (US)

Correspondence Address: John M Card;Brinks Hofer Gilson & Lione, PO Box 10395, Chicago, IL, 60610, US

(21) Appl. No.: 10/502,111

(22) PCT Filed: Feb. 3, 2003
(86) PCT No.: PCT/US03/03203

Related U.S. Application Data
(60) Provisional application No. 60/353,418, filed on Feb. 1, 2002.

(51) Int. Cl. H01L 31/0336; H01L 47/00; H01L 31/0328; H01L 31/072; H01L 31/109

(52) U.S. Cl. 257/186; 257/189

(57) ABSTRACT

The present invention includes an epitaxial structure (16) grown on a semi-insulating InP substrate (12). First, a buffer layer (14) is grown to isolate defects originated from substrates (12). Then an n-type layer (18) is grown to serve as n-contact layer to collect electrons. Next, a multiplication layer (20) is grown to provide avalanche gain for the APD device (10). Following that, an ultra-thin charge control layer (22) is grown with carbon doping. An absorption layer (24) is grown to serve as the region for creating electronhole pairs due to a photo-excitation. Finally, a p-type layer (28) is grown to serve as p-contact layer to collect holes.

### FIELD OF THE INVENTION

The present invention relates generally to the field of semiconductor-based photodetectors, and more specifically to an optimized avalanche photodiode and a method of making the same.

### BACKGROUND AND SUMMARY OF THE INVENTION

Owing to the known interaction between photons and electrons, great advances have been made in the field of photodetectors in recent years, particularly in those photodetectors that utilize semiconductor materials. One type of semiconductor-based photodetector is termed an avalanche photodiode, or APD. This type of structure is generally composed of a number of solid semiconductive materials that serve different purposes such as absorption and multiplication.

The APD structure provides the primary benefit of large gain through the action of excited charge carriers that produce large numbers of electron-hole pairs in the multiplication layer. However, an APD is so efficient at producing large numbers of charge carriers that it runs the risk of becoming saturated, thus adversely affecting the bandwidth of the device. In order to prevent charge carrier breakdown, it is imperative that the electric field be regulated within the APD itself, and in particular it is desirable to have the electric field in the multiplication layer be significantly higher than that in the absorption layer.

Traditionally, a separate absorption, grading, charge, multiplication (SAGCM) APD utilizes a grading layer to minimize hole trapping at the heterojunction interface and a charge control layer to separate the electric field between the absorption and the multiplication layers. Design of this charge control layer is extremely critical in that it should allow for a high enough electric field strength to initiate impact ionization in the multiplication layer while keeping the electric field in the absorption layer low in order to prevent tunneling breakdown.

For example, an SAGCM APD structure with an n-type multiplication layer, electrons are multiplied and a p-type doping is required to act as the charge control layer. However, a conventional beryllium or zinc p-type doping method requires a relatively thick charge control layer because of the high diffusion coefficient associated with beryllium and zinc. Due to this thick charge control region with lower doping, the carrier transit time across the charge control layer is increased, thereby reducing the overall speed of these APD devices.

By way of comparison, in the present invention the limitations manifest in a beryllium or zinc charge control layer are overcome by utilizing carbon doping. This solution results in an ultra-thin charge control layer while increasing the speed of the photodetector. Since carbon has a very small diffusion coefficient, a precise doping control can be achieved to realize a charge sheet within an ultra-thin layer of 100 angstroms or less.

The present invention includes an epitaxial structure grown on a semi-insulating InP substrate. First, a buffer layer is grown to isolate defects originated from substrates. Then an n-type layer is grown to serve as n-contact layer to collect electrons. Next, a multiplication layer is grown to provide avalanche gain for the APD device. Following that, an ultra-thin charge control layer is grown with carbon doping. An absorption layer is grown to serve as the region for creating electron-hole pairs due to a photo-excitation. Finally, a p-type layer is grown to serve as p-contact layer to collect holes. Further embodiments and advantages of the present invention are discussed below with reference to the Figures.

### BRIEF DESCRIPTION OF THE DRAWINGS

FIG. 1 is a perspective view of a charge controlled avalanche photodiode in accordance with one aspect of the present invention.

FIG. 2 is a graph depicting the spatial dependence of an electric field placed across the depth of a charge controlled avalanche photodiode.

### DETAILED DESCRIPTION OF THE PREFERRED EMBODIMENT

In accordance with a preferred embodiment of the present invention, an epitaxial structure is provided for photoconductive purposes. The photoconductive structure is an avalanche photodiode (APD) that is optimized for increased performance through a charge control layer. The particulars of the structure and method of manufacture of the present invention are discussed further herein.

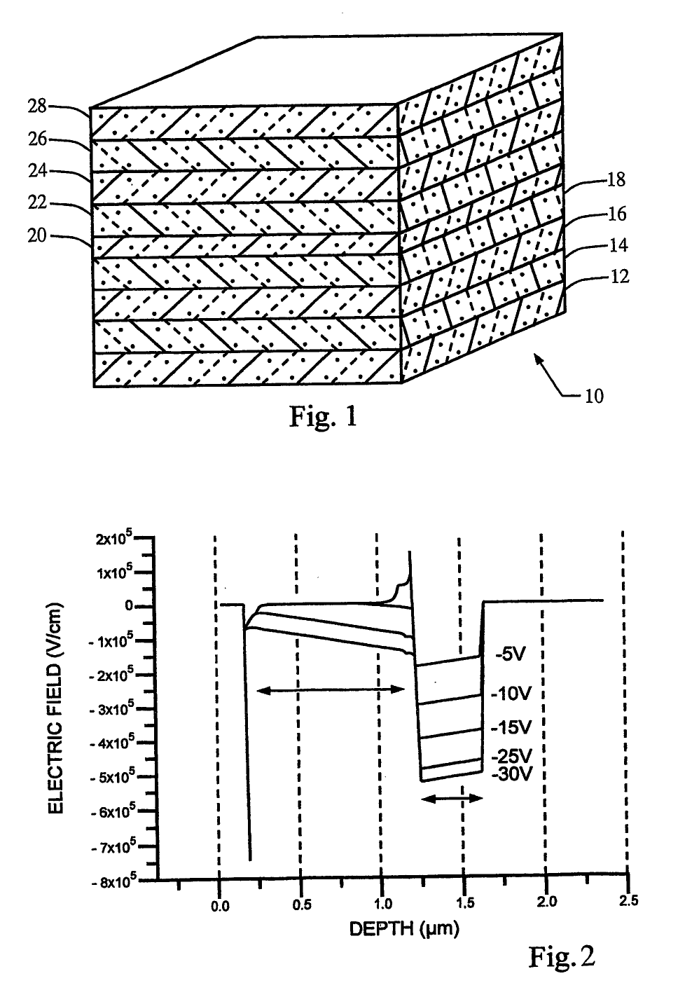

Referring to FIG. 1, a perspective view of a charge controlled APD 10 is shown in accordance with the preferred embodiment. A substrate 12 is provided as a base upon which the epitaxial structure is deposited. The charge controlled APD 10 of the present invention may be manufactured in a number suitable fashions, including molecular beam epitaxy and metal organic vapor phase epitaxy.

The substrate 12 may be composed of a semi-insulating material or alternatively the substrate may be doped Indium Phosphate (InP). A buffer layer 14 is disposed above the substrate 12 to isolate any structural or chemical defects of the substrate 12 from the remaining structure.

An n-type layer 16 is disposed upon the buffer layer 14 to serve as an n-contact layer and thus collect electrons cascading through the charge controlled APD 10. The n-type layer may be composed of one of Indium Phosphate (InP) or Indium Aluminum Arsenide (InAlAs). Disposed upon the n-type layer 16 is a multiplication layer 18 composed of InAlAs. The multiplication layer 18 provides the avalanche effect in which the current density of the electrons is amplified, thereby providing the APD gain.

A charge control layer 20 is disposed upon the multiplication layer 18 in order to isolate the multiplication layer 18 from the top layers of the charge controlled APD 10. In the preferred embodiment, the charge control layer 20 is composed of carbon-doped InAlAs. The charge control layer 20 is deposited only to a thickness of less than 100 angstroms. It is possible that the charge control layer 20 could be as few as 2 angstroms in thickness, thus representing a two-dimensional charge sheet. Preferably, therefore, the charge control layer 20 between 2 and 100 angstroms in thickness.

Two digital graded layers 22, 26 are disposed beneath and above an absorption layer 24 in order to minimize any carrier trapping due to the bandgap between Indium Gallium Arsenide (InGaAs) and InAlAs materials. The first digital graded layer 22 is disposed upon the charge control layer 20. The absorption layer 24 utilized for creating electron-hole pairs is disposed upon the digital graded layer 22. The second digital graded layer 26 is then disposed upon the absorption layer 24.

In the preferred embodiment, both the first and the second digital graded layers 22, 26 are composed of Indium Aluminum Gallium Arsenide (InAlGaAs). The absorption layer 24 is composed of InGaAs in order to maximize the number of electron-hole pairs produced through photo-excitation.

A p-type layer 28 serving as a p-contact layer is disposed on the second digital graded layer 26 in order to collect holes in a manner analogous to the n-type layer 16. The p-type layer 26 is preferably one of InP or InAlAs, as described above for the n-type layer 16. In related embodiments, the p-type layer 28 and the n-type layer 16 may be of the same material, or alternatively, they may be composed of differing materials within the set of InP or InAlAs.

The charge controlled APD 10 described with reference to FIG. 1 provides much improved performance over a typical epitaxial APD. In particular, the charge control layer 20 is particular adept at maintaining a high electric field in the multiplication layer 18 while maintaining a low electric field in the absorption layer 24.

FIG. 2 is a graph representative of electric field values measured for dependency upon depth in the charge controlled APD 10 against various voltage biases. In particular, it is notable that the absorption layer 24 is typically disposed between 0.25 and 1.25 μm from the surface of the p-type layer 28. Similarly, the multiplication layer 18 may be disposed between 1.25 and 1.75 μm from the surface of the p-type layer 28.

Accordingly, it is evident from FIG. 2 that the charge control layer 20, disposed between the absorption layer 24 and the multiplication layer 18, is responsible for a increase in the electric field between the respective layers. In particular, for a −5V bias, the electric field in the absorption layer 24 is approximately zero, whereas the electric field in the multiplication layer 18 is on the order of −1.75×10³ V/cm. For a voltage of −30 volts, the electric field in the absorption layer 24 is approximately −1.0×10³, whereas the electric field in the multiplication layer 18 is on the order of −5.0×10³ V/cm. Moreover, as the thickness of the charge control layer 20 is less than 100 angstroms, it also provides substantially decreased carrier transit time, resulting in overall efficiencies in the APD response time.

As described, the present invention consists of an avalanche photodiode having a charge control layer. In particular, the charge control layer is carbon-doped and less than 100 angstroms in thickness, thereby providing an increased electric field gradient between the absorption and multiplication layers of the device. It should be apparent to those skilled in the art that the above-described embodiments are merely illustrative of but a few of the many possible specific embodiments of the present invention. Numerous and various other arrangements can be readily devised by those skilled in the art without departing from the spirit and scope of the invention as defined in the following claims.

1. An avalanche photodiode comprising:
an absorption layer disposed on a substrate layer;
a multiplication layer disposed on the substrate layer; and
a carbon-doped charge control layer disposed between the absorption layer and the multiplication layer.

2. The avalanche photodiode of claim 1 wherein the absorption layer is disposed between a first digital graded layer and a second digital graded layer.

3. The avalanche photodiode of claim 1 further comprising an n-type contact layer disposed between the multiplication layer and the substrate.

4. The avalanche photodiode of claim 1 further comprising a p-type contact layer.

5. The avalanche photodiode of claim 1 further comprising a buffer layer disposed between the n-type contact layer and the substrate.

6. The avalanche photodiode of claim 1 wherein the absorption layer is InGaAs.

7. The avalanche photodiode of claim 1 wherein the multiplication layer is InAlAs.

8. The avalanche photodiode of claim 1 wherein the carbon-doped charge control layer is carbon-doped InAlAs.

9. The avalanche photodiode of claim 1 wherein the carbon-doped charge control layer is between 2 and 100 angstroms in thickness.

10. The avalanche photodiode of claim 1 wherein the carbon-doped charge control layer is between 5 and 50 angstroms in thickness.

11. The avalanche photodiode of claim 1 wherein the carbon-doped charge control layer is between 5 and 35 angstroms in thickness.

12. The avalanche photodiode of claim 2 wherein the first digital graded layer is InAlGaAs, and further wherein the second digital graded layer is InAlGaAs.

13. The avalanche photodiode of claim 3 wherein the n-type contact layer is one of InP or InAlA.

14. The avalanche photodiode of claim 4 wherein the p-type contact layer is one of InP or InAlAs.

15. A method of fabricating an avalanche photodiode comprising the steps of:
providing a substrate layer;
depositing a multiplication layer;
depositing a carbon-doped charge control layer; and
depositing an absorption layer.

16. The method of claim 15 further comprising the step of depositing an n-type layer to collect electrons.

17. The method of claim 15 further comprising the step of depositing a p-type layer to collect holes.

18. The method of claim 15 further comprising the step of depositing a digital grading layer to prevent carrier trapping between bandgap offsets.

19. The method of claim 15 further comprising the step of doping an InAlAs material with carbon.
